(19) United States
(12) Patent Application Publication
(10) Pub. No.: US 2008/0157140 A1
(43) Pub. Date: Jul. 3, 2008

(54) IMAGE SENSOR AND FABRICATING METHOD THEREOF

(76) Inventor: Eun-Sang Cho, Gyeongi-do (KR)

Correspondence Address: SHERR & NOURSE, PLLC, 620 HERNDON PARKWAY, SUITE 200, HERNDON, VA, 20170, US

(21) Appl. No.: 11/869,489

(22) Filed: Oct. 9, 2007

(30) Foreign Application Priority Data
Dec. 27, 2006 (KR) 10-2006-0135765

(51) Int. Cl. H01L 31/062; H01L 21/00

(52) U.S. Cl. 257/292; 438/70; 257/E31.001

(57) ABSTRACT

An image sensor including a semiconductor substrate having a photodiode, at least one interlayer dielectric layer formed over the semiconductor substrate and an oxide layer passes through the interlayer dielectric layer.

The present application claims priority under 35 U.S.C. 119 and 35 U.S.C. 365 to Korean Patent Application No. 10-2006-0135765 (filed on Dec. 27, 2006), which is hereby incorporated by reference in its entirety.

### BACKGROUND

Aspects of semiconductor technology include an image sensor, which converts an optical image into an electric signal. A CMOS image sensor may include a micro lens formed on the top surface thereof. Light condensed by the microlens passes through a color filter layer and a plurality of interlayer dielectric layers, and then reaches a photodiode. The photodiode converts the light into an electric signal.

One of the challenges in the image sensor is to improve the rate of converting an incident optical signal into the electrical signal, i.e., enhancing sensitivity. One explanation for the reduction in sensitivity may be that a portion of light is refracted or reflected by the interfaces between the interlayer dielectric layers when the light passing through the microlens and color filter layer reaches the interlayer dielectric layers. Meaning, a portion of light may be reflected or refracted and does not reach the photodiode, causing the sensitivity to be reduced.

### SUMMARY

Embodiments relate to an image sensor and a method of fabricating an image sensor which efficiently transmits incident light to a photodiode to improve sensitivity.

Embodiments relate to an image sensor including: a semiconductor substrate having a photodiode; at least one interlayer dielectric layer formed on and/or over the semiconductor substrate; and an oxide layer passing through the interlayer dielectric layer formed on and/or over the photodiode.

Embodiments relate to a method of fabricating an image sensor including at least one of the following steps: forming at least one interlayer dielectric layer on and/or over a semiconductor substrate including a photodiode; forming a through hole passing through the interlayer dielectric layer formed on and/or over the photodiode; and filling the through hole with an oxide layer.

### DRAWINGS

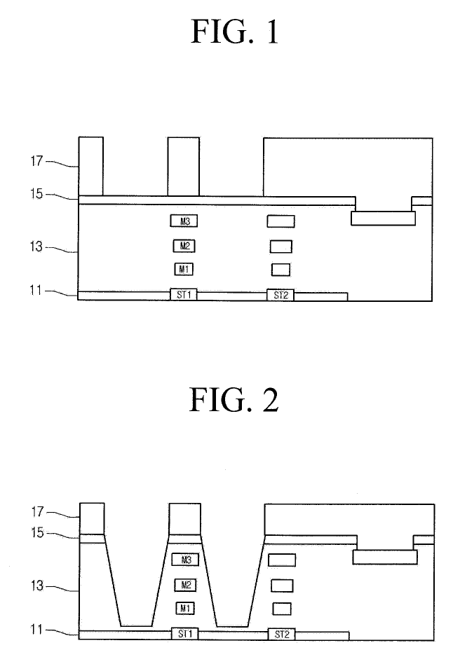

Example FIGS. 1 to 4 illustrate a method of fabricating an image sensor, in accordance with embodiments.

### DESCRIPTION

In the description, it will be understood that when a layer (or film), region, pattern, or structure is referred to as being “on and/or over” another substrate, layer (or film), region, pad, or pattern, it can be directly on the another substrate, layer (or film), region, pad, or pattern, or an intervening layer (or film), region, pad, pattern, or structure may also be present. Further, it will be understood that when a layer (or film), region, pattern, or structure is referred to as being “below and/or under” another substrate, layer (or film), region, pad, or pattern, it can be directly under the another substrate, layer (or film), region, pad, or pattern, or an intervening layer (or film), region, pad, pattern, or structure may also be present. Therefore, the meanings of the terms are determined in accordance with embodiments.

As illustrated in example FIG. 1, at least one interlayer dielectric layer 13 can be formed on a semiconductor substrate including photodiode 11 formed thereon. Interlayer dielectric layer 13 may be formed of a plurality of layers, and such plurality of layers may be formed of media having different refractive indexes. A plurality of metal wiring layers may be formed in interlayer dielectric layer 13. After that, passivation layer 15 may be formed on interlayer dielectric layer 13. Passivation layer 15 may be formed of silicon nitride (SiN). A photoresist layer can then be formed on passivation layer 15, and the photoresist layer patterned to form photoresist pattern 17.

As illustrated in example FIG. 2, a through hole can be formed to pass or extend through interlayer dielectric layer 13 and passivation layer 15. An upper width of the through hole may be greater than a lower width thereof, i.e., from interlayer dielectric layer 13 to passivation layer 15, the width of the through hole may gradually increase. During formation of the through hole, interlayer dielectric layer 13 may be etched using a deep trench reactive ion etching (RIE) process.

In accordance with embodiments, the deep trench RIE may be performed under the following conditions: supplying CF₄, Ar, and O₂ at a flow rate ratio of 12:55:1, respectively. Particularly, CF₄, Ar, and O₂ may be supplied such that the flow rate of CF₄ ranges from between approximately 100 sccm to 140 sccm, the flow rate of Ar ranges from between approximately 500 sccm to 600 sccm, and the flow rate of O₂ ranges from between approximately 8 sccm to 12 sccm.

The deep trench RIE process may be performed according to the following table.

| | SiN | Oxide |
|---|---|---|
| Pressure [mT] | 40 | 55 |
| RF POWER (TOP) [W] | 1,800 | 2,000 |
| RF POWER (BOTTOM) [W] | 2,000 | 2,000 |
| CF₄ [sccm] | 0 | 120 |
| Ar [sccm] | 560 | 550 |
| O₂ [sccm] | 18 | 10 |
| CHF₈ [sccm] | 96 | 0 |
| C₅F₈ [sccm] | 0 | 14 |

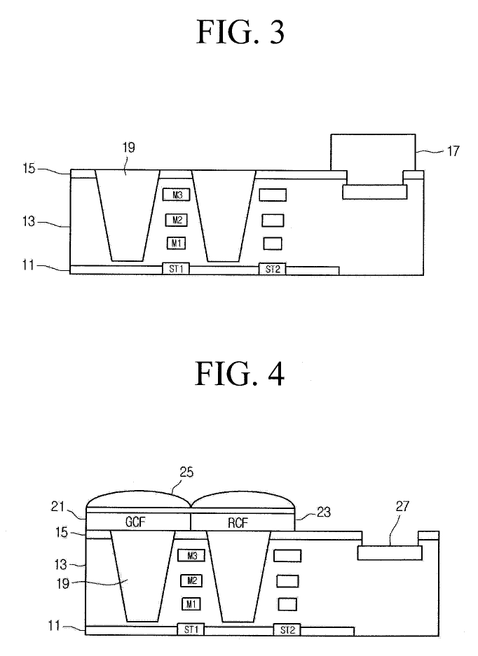

As illustrated in example FIG. 3, oxide layer 19 can be filled in the through hole. Oxide layer 19 may be formed using a deposition process and/or a coating process. Oxide layer 19 can serve as a wave guide. Oxide layer 19 may be a single layer having no boundary layer therein. Hence, incident light is not reflected or scattered by the interface between layers.

As illustrated in example FIG. 4, color filter layer 21 can then be formed on interlayer dielectric layer 13 and oxide layer 19 and microlens 25 formed on color filter layer 21.

Passivation layer 15 may be further formed on interlayer dielectric layer 13. In addition, overcoat layer 23 may be further formed between color filter layer 21 and microlens 25. Thereafter, an uppermost surface of pad part 27 formed in interlayer dielectric layer 13 may be exposed.

The metal wiring layers can be formed different from one another. Interlayer dielectric layer 13 formed in accordance with embodiments may also be formed as a multi-layered structure. The characteristics of materials of each layer in a multi-layered interlayer dielectric layer can be different from each other, and the layers can also differ from one another in dielectric constant, optical constants, and the like (n, k, etc.) during processing. Hence, an optical path of light condensed by microlens 25 may be changed or the light may be severely reflected and refracted.

In accordance with embodiments, a through hole passing through interlayer dielectric layer 13 can be formed and subsequently filled with a single medium to efficiently transmit condensed light to photodiode 11.

In accordance with embodiments, the image sensor and the fabricating method thereof incident light can be efficiently transmitted to the photodiode to enhance sensitivity.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate including a photodiode;
at least one interlayer dielectric layer formed over the semiconductor substrate; and
an oxide layer passing through the interlayer dielectric layer.

2. The apparatus of claim 1, further comprising:
a color filter layer formed on the interlayer dielectric layer; and
at least one micro lens formed on the color filter layer.

3. The apparatus of claim 1, wherein the width of the oxide layer gradually increases from a lower portion thereof to an upper portion thereof.

4. The apparatus of claim 1, wherein the interlayer dielectric layer comprises a plurality of layers.

5. The apparatus of claim 4, wherein the plurality of layers comprises media having different refractive indexes.

6. A method comprising:
forming at least one interlayer dielectric layer over a semiconductor substrate where a photodiode is formed;
forming at least one through hole in the interlayer dielectric layer; and
filling the through hole with an oxide layer.

7. The method of claim 6, wherein the oxide layer is formed using a deposition process.

8. The method of claim 6, wherein the oxide layer is formed using a coating process.

9. The method of claim 6, wherein the width of the oxide layer gradually increases from a lower portion thereof to an upper portion thereof.

10. The method of claim 6, further comprising:
forming a color filter layer on the at least one interlayer dielectric layer and the oxide layer; and
forming at least one micro lens on the color filter layer.

11. The method of claim 6, wherein the at least one interlayer dielectric layer comprises a multi-layered structure having a plurality of layers.

12. The method of claim 11, wherein the plurality of layers comprises media having different refractive indexes.

13. The method of claim 6, wherein the through hole is formed using a deep trench reactive ion etching process.

14. The method of claim 13, wherein performing the deep trench reactive ion etching process comprises supplying CF₄, Ar, and O₂ at a flow rate ratio of 12:55:1.

15. The method of claim 14, wherein a flow rate of CF₄ ranges from between approximately 100 sccm to 140 sccm, a flow rate of Ar ranges from between approximately 500 sccm to 600 sccm, and a flow rate of O₂ ranges from between approximately 8 sccm to 12 sccm.

16. The method of claim 6, wherein the oxide layer 19 is formed as a single layer having no boundary layer therein.

17. The method of claim 6, further comprising forming a plurality of metal wiring layers in the interlayer dielectric layer.

18. The method of claim 17, further comprising forming a passivation layer over the at least one interlayer dielectric layer after forming the plurality of metal wiring layers.

19. The method of claim 10, further comprising forming an overcoat layer between the color filter layer and the at least one microlens.

20. The method of claim 19, exposing an uppermost surface of a pad part formed in the interlayer dielectric layer.
